(19) United States
(12) Patent Application Publication
(10) Pub. No.: US 2021/0390225 A1
(43) Pub. Date: Dec. 16, 2021

(54) REALISM IN LOG-BASED SIMULATIONS

(71) Applicant: Waymo LLC, Mountain View, CA (US)

(72) Inventors: Han Yu, Cupertino, CA (US); Yang-hua Chu, Menlo Park, CA (US); Xiaoyi Liu, Mountain View, CA (US)

(21) Appl. No.: 16/897,325

(22) Filed: Jun. 10, 2020

(51) Int. Cl. G06F 30/20; B60W 60/00

(52) U.S. Cl. CPC G06F 30/20; G05D 1/0088; B60W 60/0027

(57) ABSTRACT

Aspects of the disclosure relate to improving realism in simulations for testing software for operating a vehicle in an autonomous driving mode. In one instance, an initial observation of a road user object may be identified in a log data segment captured by a perception system of a vehicle. The perception system having one or more sensors. The initial observation includes a point in time and an initial location of the road user object. A distance traveled by the road user object from a start of the log data segment to the point in time may be determined. A starting location for the road user object may be determined using the distance traveled. A trajectory for the road user object may be determined between the starting location and the initial location of the road user object. The trajectory may be appended to the log data segment.

### BACKGROUND

Autonomous vehicles, such as vehicles which do not require a human driver when operating in an autonomous driving mode, may be used to aid in the transport of passengers or items from one location to another. An important component of an autonomous vehicle is the perception system, which allows the vehicle to perceive and interpret its surroundings using sensors such as cameras, radar, LIDAR sensors, and other similar devices. For instance, the perception system and/or the vehicle's computing devices may process data from these sensors in order to identify objects as well as their characteristics such as location, shape, size, orientation, heading, acceleration or deceleration, type, etc. This information is critical to allowing the vehicle's computing systems to make appropriate driving decisions for the vehicle.

### BRIEF DESCRIPTION OF THE DRAWINGS

FIG. 1 is a functional diagram of an example vehicle in accordance with aspects of the disclosure.

FIG. 2 is an example of map information in accordance with aspects of the disclosure.

FIG. 3 is an example diagram of a vehicle in accordance with aspects of the disclosure.

FIG. 4 is an example pictorial diagram of a system in accordance with aspects of the disclosure.

FIG. 5 is an example functional diagram of a system in accordance with aspects of the disclosure.

FIGS. 6A-6B are an example of a first log data segment in accordance with aspects of the disclosure.

FIGS. 6C-6D are an example of a first simulation in accordance with aspects of the disclosure.

FIGS. 7A-7B are an example of a second log data segment in accordance with aspects of the disclosure.

FIGS. 7C-7D are an example of a second simulation in accordance with aspects of the disclosure.

FIG. 8 is an example interpolation for the first log data segment in accordance with aspects of the disclosure.

FIG. 9 is an example interpolation for the second log data segment in accordance with aspects of the disclosure.

FIG. 10 is an example interpolation in accordance with aspects of the disclosure.

FIG. 11 is an example flow diagram in accordance with aspects of the disclosure.

FIG. 12 is an example flow diagram in accordance with aspects of the disclosure.

### SUMMARY

Aspects of the disclosure provide a method for improving realism in simulations for testing software for operating a vehicle in an autonomous mode. The method including identifying, by one or more processors, an initial observation of a road user object in a log data segment captured by a perception system of a vehicle, the perception system having one or more sensors, the initial observation including a point in time and an initial location of the road user object; estimating, by the one or more processors, a distance traveled by the road user object from a start of the log data segment to the point in time; determining, by the one or more processors, a starting location for the road user object using the distance traveled; determining, by the one or more processors, a trajectory for the road user object between the starting location and the initial location of the road user object; and appending, by the one or more processors, the trajectory to the log data segment.

In one example, the initial observation includes a speed of the road user object at the point in time, and estimating the distance traveled by the road user object is based on the speed. In another example, estimating the distance traveled is further based on a difference between the point in time and the start of the log data segment. In this example, determining the starting location includes identifying a lane for the road user object, and traversing the lane backwards from the initial location using the distance traveled to determine the starting location. In this example, the initial observation includes a heading for the road user object and wherein identifying the lane for the road user object is based on the heading for the road user object and a heading of the lane. In addition or alternatively, the initial observation includes a heading for the road user object and wherein identifying the lane for the road user object includes using pre-stored map information to identify a closest lane to the initial location of the road user object having a heading that is consistent with the heading for the road user object. In addition or alternatively, the starting location is at a center of the lane. In another example, determining the trajectory includes determining a plurality of waypoints between the starting location and the initial location of the road user object and a corresponding plurality of timestamps between a beginning of the log data segment and the point in time. In this example, determining the plurality of waypoints and the corresponding plurality of timestamps is based on a frame rate of the log data segment. In another example, the method also includes using the log data segment and the appended trajectory to run a simulation.

Another aspect of the disclosure provides a method for improving realism in simulations for testing software for operating a vehicle in an autonomous driving mode. The method includes: identifying, by one or more processors, a final observation of a road user object in a log data segment captured by a perception system of a vehicle, the perception system having one or more sensors, the final observation including a point in time and a final location of the road user object; estimating, by the one or more processors, a distance traveled by the road user object from the point in time to an end of the log data segment; determining, by the one or more processors, an ending location for the road user object using the distance traveled; determining, by the one or more processors, a trajectory for the road user object between the final location of the road user object and the ending location; and appending, by the one or more processors, the trajectory to the log data segment.

In this example, the final observation includes a speed of the road user object at the point in time, and wherein estimating the distance traveled by the road user object is based on the speed. In another example, estimating the distance traveled is further based on a difference between the point in time and the end of the log data segment. In one example, determining the ending location includes identifying a lane for the road user object and traversing the lane forward from the final location using the distance traveled to determine the ending location. In this example, the final observation includes a heading for the road user object and wherein identifying the lane for the road user object is based on the heading for the road user object and a heading of the lane. In addition or alternatively, the final observation includes a heading for the road user object and wherein identifying the lane for the road user object includes using pre-stored map information to identify a closest lane to the final location of the object having a heading that is consistent with the heading for the road user object. In addition or alternatively, the ending location is at a center of the lane. In another example, determining the trajectory includes determining a plurality of waypoints between the ending location and the final location of the road user object and a corresponding plurality of timestamps between the point in time and an end of the log data segment. In this example, determining the plurality of waypoints and the corresponding plurality of timestamps is based on a frame rate of the log data segment. In another example, the method also includes using the log data segment and the appended trajectory to run a simulation.

### DETAILED DESCRIPTION

### Overview

The technology relates to improving realism in log-based simulations using software for vehicles operating autonomously. The log-based simulations correspond to simulations which are run using log data segments collected by a vehicle operating in an autonomous mode over some brief period of time such as 1 minute or more or less. The log data may include information from the vehicle's various systems including perception, routing, planning, positioning, etc. At the same time, the actual vehicle is replaced with a simulated vehicle which can make decisions using software for controlling the vehicle autonomously. By doing so, the software can be rigorously tested.

However, when running such simulations, if the behavior of the simulated vehicle is different from the vehicle that captured the log data segment, the simulated vehicle and the vehicle that captured the log data may have different fields of view or perspectives. Because of unavoidable limits on the sensor data included in the logs due to the limits of these devices and other factors like occlusions, the log data will not include the absolute “ground truth” of the world or rather, all sensor data from all possible perspectives for the log data segment. As a result, problems may occur when objects that were previously occluded with respect to the vehicle that captured the log data segment are now interacting with the simulated vehicle. Such objects may appear “from nowhere” and may “pop up” and surprise the simulated vehicle.

To address these issues, the log data may be analyzed in order to backward or forward interpolate the trajectories of objects. For the backward interpolation, the log data segment may first be analyzed to identify objects, including road users such as pedestrians, bicyclists and other vehicles. The analysis may also include identifying a point in time when each road user object is first observed in the log data segment.

To estimate a distance traveled by the road user object, the amount of time between the beginning of the log data segment and the point at which the object is first observed may be determined. For any road user objects which were first observed at a point in time after the beginning of the log data segment, the initial speed of those road user objects may be identified, or rather, the estimated speed of the road user object at the point in time when the road user object is first observed.

Next, a lane for the road user object when the road user object is first observed may be determined. The lane may be determined based on both the location of the road user as well as the heading of the road user at the point in time when the road user was first observed. Again, this information may be included in the log data segment. By comparing the location to pre-stored map information identifying the shape and locations of lanes, the closest lane having the same or similar heading as the road user object may be identified.

The lane may then be traversed backwards (opposite of the direction of the heading of the object or the lane) the estimated distance traveled to determine a starting location for the road user object at the beginning of the log segment (or future simulation). From this starting location, a plurality of waypoints (intermediate states for the road user object) and corresponding timestamps for the object may be determined. Each waypoint may be determined based on a frame rate of the log data. This frame rate may be dictated by a frame rate of the sensors that captured the sensor data of the log data segment.

A similar approach may be used to interpolate forward. However, in such cases, the log data segment is analyzed to determine a last point in time when each road user object is observed. Also, rather than traversing backward along the nearest lane with the same or similar heading, the lane is traversed forward to find an ending location for the object at the end of the log data segment. From this ending location, a plurality of waypoints and timestamps for the object may be determined.

A trajectory may then be determined for the road user object. The trajectory may include each of the waypoints as well as a timestamp for the road user object. This trajectory (including road user objects, waypoints—including starting or ending location—and timestamps) may then be appended to the log data segment and used to run simulations. These simulations may be used to evaluate the performance of the autonomous vehicle software used to control the simulated vehicle in the simulation, for instance by identifying collisions, near collisions, uncomfortable levels of braking, swerving, and other events. Simulations may also be used to test other aspects of the vehicle's systems, such as recall on the ability to identify specific types of road users.

In some instances, simulations may be run which involve replacing the road user object with a model agent which can react to the actions of the simulated vehicle as well as other objects in the log data segment. Because the appended information will include the location of a road user object before it was actually observed by the vehicle that captured the log data, the road user object can actually be replaced by a model agent at a point in time prior to the road user object being observed in the log data segment.

The features described herein may provide for a safe, effective, and realistic way of testing software for autonomous vehicles while at the same time improving the realism of such simulations. For example, by appending the information to log data segments, this may enable simulations to be run without the concern of objects appearing “from nowhere” or “popping up” and surprising the simulated vehicle in an unrealistic way. In addition, as noted above, the point at which such road user objects may be replaced by model agents is earlier than if such information were not appended to the log data segments. Moreover, in situations where a new agent is added (not necessarily replacing a road user object) to a simulation, the features described herein may identify exactly where the new agent should appear at the start of the simulation. Both of these features may allow for the running of more realistic simulations that are significantly longer than 1 minute or more or less. Finally, as the perception system may take some time (e.g. a warm up period) before the system can confidently detect an object and its characteristics, by injecting a road user object or agent earlier into a simulation, this can save the “warm up” time and improve sensor recall in the simulation.

### Example Systems

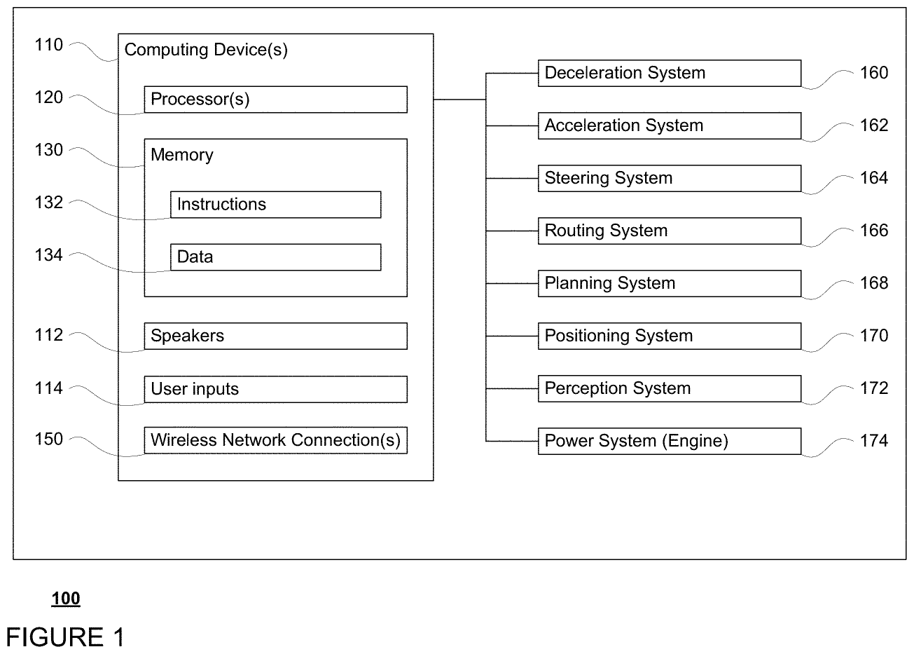

As shown in FIG. 1, a vehicle 100 in accordance with one aspect of the disclosure includes various components. While certain aspects of the disclosure are particularly useful in connection with specific types of vehicles, the vehicle may be any type of vehicle including, but not limited to, cars, trucks, motorcycles, buses, recreational vehicles, etc. The vehicle may have one or more computing devices, such as computing device 110 containing one or more processors 120, memory 130 and other components typically present in general purpose computing devices.

The memory 130 stores information accessible by the one or more processors 120, including instructions 132 and data 134 that may be executed or otherwise used by the processor 120. The memory 130 may be of any type capable of storing information accessible by the processor, including a computing device-readable medium, or other medium that stores data that may be read with the aid of an electronic device, such as a hard-drive, memory card, ROM, RAM, DVD or other optical disks, as well as other write-capable and read-only memories. Systems and methods may include different combinations of the foregoing, whereby different portions of the instructions and data are stored on different types of media.

The instructions 132 may be any set of instructions to be executed directly (such as machine code) or indirectly (such as scripts) by the processor. For example, the instructions may be stored as computing device code on the computing device-readable medium. In that regard, the terms “instructions” and “programs” may be used interchangeably herein. The instructions may be stored in object code format for direct processing by the processor, or in any other computing device language including scripts or collections of independent source code modules that are interpreted on demand or compiled in advance. Functions, methods and routines of the instructions are explained in more detail below.

The data 134 may be retrieved, stored or modified by processor 120 in accordance with the instructions 132. For instance, although the claimed subject matter is not limited by any particular data structure, the data may be stored in computing device registers, in a relational database as a table having a plurality of different fields and records, XML documents or flat files. The data may also be formatted in any computing device-readable format.

The one or more processor 120 may be any conventional processors, such as commercially available CPUs or GPUs. Alternatively, the one or more processors may be a dedicated device such as an ASIC or other hardware-based processor. Although FIG. 1 functionally illustrates the processor, memory, and other elements of computing device 110 as being within the same block, it will be understood by those of ordinary skill in the art that the processor, computing device, or memory may actually include multiple processors, computing devices, or memories that may or may not be stored within the same physical housing. For example, memory may be a hard drive or other storage media located in a housing different from that of computing device 110. Accordingly, references to a processor or computing device will be understood to include references to a collection of processors or computing devices or memories that may or may not operate in parallel.

The computing devices 110 may also be connected to one or more speakers 112 as well as one or more user inputs 114. The speakers may enable the computing devices to provide audible messages and information, to occupants of the vehicle, including a driver. In some instances, the computing devices may be connected to one or more vibration devices configured to vibrate based on a signal from the computing devices in order to provide haptic feedback to the driver and/or any other occupants of the vehicle. As an example, a vibration device may consist of a vibration motor or one or more linear resonant actuators placed either below or behind one or more occupants of the vehicle, such as embedded into one or more seats of the vehicle.

The user input may include a button, touchscreen, or other devices that may enable an occupant of the vehicle, such as a driver, to provide input to the computing devices 110 as described herein. As an example, the button or an option on the touchscreen may be specifically designed to cause a transition from the autonomous driving mode to the manual driving mode or the semi-autonomous driving mode.

In one aspect the computing devices 110 may be part of an autonomous control system capable of communicating with various components of the vehicle in order to control the vehicle in an autonomous driving mode. For example, returning to FIG. 1, the computing devices 110 may be in communication with various systems of vehicle 100, such as deceleration system 160, acceleration system 162, steering system 164, routing system 166, planning system 168, positioning system 170, and perception system 172 in order to control the movement, speed, etc. of vehicle 100 in accordance with the instructions 132 of memory 130 in the autonomous driving mode. In this regard, each of these systems may de one or more processors, memory, data and instructions. Such processors, memories, instructions and data may be configured similarly to one or more processors 120, memory 130, instructions 132, and data 134 of computing device 110.

As an example, computing devices 110 may interact with deceleration system 160 and acceleration system 162 in order to control the speed of the vehicle. Similarly, steering system 164 may be used by computing devices 110 in order to control the direction of vehicle 100. For example, if vehicle 100 is configured for use on a road, such as a car or truck, the steering system may include components to control the angle of wheels to turn the vehicle.

Planning system 168 may be used by computing devices 110 in order to determine and follow a route generated by a routing system 166 to a location. For instance, the routing system 166 may use map information to determine a route from a current location of the vehicle to a drop off location. The planning system 168 may periodically generate trajectories, or short-term plans for controlling the vehicle for some period of time into the future, in order to follow the route (a current route of the vehicle) to the destination. In this regard, the planning system 168, routing system 166, and/or data 134 may store detailed map information, e.g., highly detailed maps identifying the shape and elevation of roadways, lane lines, intersections, crosswalks, speed limits, traffic signals, buildings, signs, real time traffic information, vegetation, or other such objects and information. In addition, the map information may identify area types such as constructions zones, school zones, residential areas, parking lots, etc.

The map information may include one or more roadgraphs or graph networks of information such as roads, lanes, intersections, and the connections between these features which may be represented by road segments. Each feature may be stored as graph data and may be associated with information such as a geographic location and whether or not it is linked to other related features, for example, a stop sign may be linked to a road and an intersection, etc. In some examples, the associated data may include grid-based indices of a roadgraph to allow for efficient lookup of certain roadgraph features.

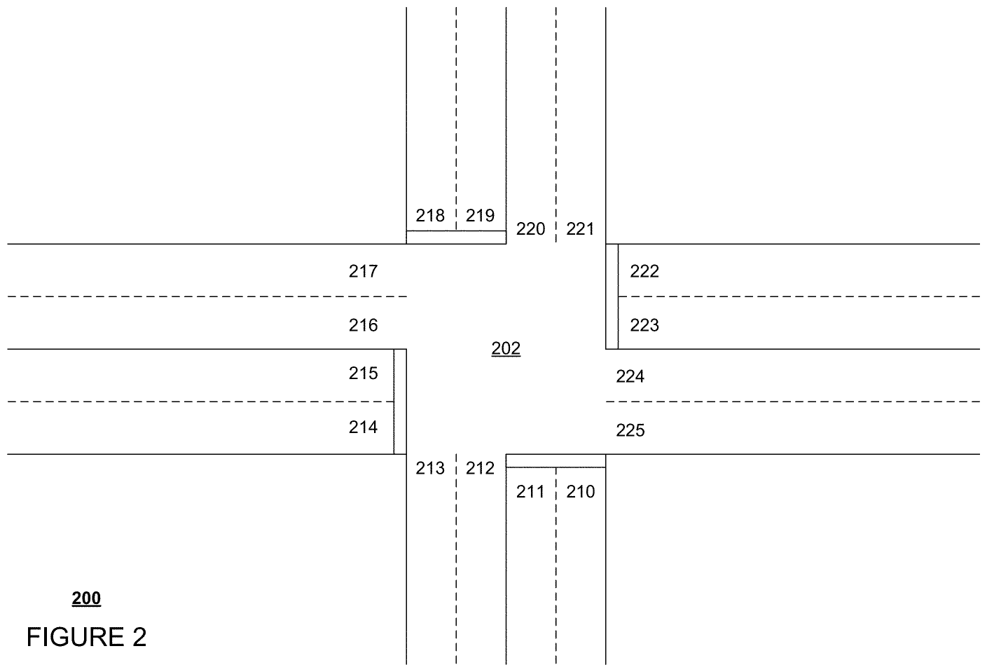

FIG. 2 is an example of map information 200 for a section of roadway including intersection 202. The map information 200 may be a local version of the map information stored in the memory 130 of the computing devices 110. Other versions of the map information may also be stored in the storage system 450 discussed further below. In this example, the map information 200 includes information identifying the shape, location, and other characteristics of lanes 210-225. Although not shown or called out, the map information may include the shapes, locations and other characteristics of various other features such as lane lines, traffic lights, stop lines, crosswalks, sidewalks, stop signs, yield signs and so on.

While the map information may be an image-based map, the map information need not be entirely image based (for example, raster). For example, the map information may include one or more roadgraphs or graph networks of information such as roads, lanes, intersections represented as nodes, and the connections between these features which may be represented by road segments. Each feature may be stored as graph data and may be associated with information such as a geographic location and whether or not it is linked to other related features, for example, a stop sign may be linked to a road and an intersection, etc. In some examples, the associated data may include grid-based indices of a roadgraph to allow for efficient lookup of certain roadgraph features.

Positioning system 170 may be used by computing devices 110 in order to determine the vehicle's relative or absolute position on a map and/or on the earth. The positioning system 170 may also include a GPS receiver to determine the device's latitude, longitude and/or altitude position relative to the Earth. Other location systems such as laser-based localization systems, inertial-aided GPS, or camera-based localization may also be used to identify the location of the vehicle. The location of the vehicle may include an absolute geographical location, such as latitude, longitude, and altitude as well as relative location information, such as location relative to other cars immediately around it which can often be determined with less noise that absolute geographical location.

The positioning system 170 may also include other devices in communication with the computing devices of the computing devices 110, such as an accelerometer, gyroscope or another direction/speed detection device to determine the direction and speed of the vehicle or changes thereto. By way of example only, an acceleration device may determine its pitch, yaw or roll (or changes thereto) relative to the direction of gravity or a plane perpendicular thereto. The device may also track increases or decreases in speed and the direction of such changes. The device's provision of location and orientation data as set forth herein may be provided automatically to the computing device 110, other computing devices and combinations of the foregoing.

The perception system 172 also includes one or more components for detecting objects external to the vehicle such as other vehicles, obstacles in the roadway, traffic signals, signs, trees, etc. For example, the perception system 172 may include lasers, sonar, radar, cameras and/or any other detection devices that record data which may be processed by the computing devices of the computing devices 110. In the case where the vehicle is a passenger vehicle such as a minivan, the minivan may include a laser or other sensors mounted on the roof or other convenient location.

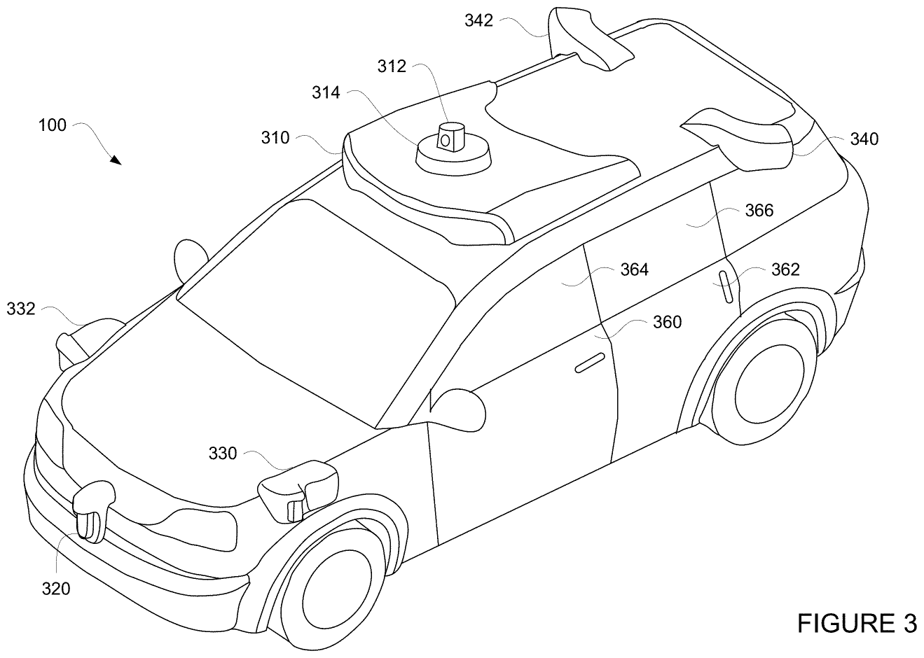

For instance, FIG. 3 is an example external view of vehicle 100. In this example, roof-top housing 310 and roof-top housings 312, 314 may include a LIDAR sensor as well as various cameras and radar units. In addition, housing 320 located at the front end of vehicle 100 and housings 330, 332 on the driver's and passenger's sides of the vehicle may each store a LIDAR sensor. For example, housing 330 is located in front of doors 360, 362 which also include windows 364, 366. Vehicle 100 also includes housings 340, 342 for radar units and/or cameras also located on the roof of vehicle 100. Additional radar units and cameras (not shown) may be located at the front and rear ends of vehicle 100 and/or on other positions along the roof or roof-top housing 310.

The computing devices 110 may be capable of communicating with various components of the vehicle in order to control the movement of vehicle 100 according to primary vehicle control code of memory of the computing devices 110. For example, returning to FIG. 1, the computing devices 110 may include various computing devices in communication with various systems of vehicle 100, such as deceleration system 160, acceleration system 162, steering system 164, routing system 166, planning system 168, positioning system 170, perception system 172, and power system 174 (i.e. the vehicle's engine or motor) in order to control the movement, speed, etc. of vehicle 100 in accordance with the instructions 132 of memory 130.

The various systems of the vehicle may function using autonomous vehicle control software in order to determine how to and to control the vehicle. As an example, a perception system software module of the perception system 172 may use sensor data generated by one or more sensors of an autonomous vehicle, such as cameras, LIDAR sensors, radar units, sonar units, etc., to detect and identify objects and their features. These features may include location, type, heading, orientation, speed, acceleration, change in acceleration, size, shape, etc. In some instances, features may be input into a behavior prediction system software module which uses various behavior models based on object type to output a predicted future behavior for a detected object.

In other instances, the features may be put into one or more detection system software systems or modules, such as a traffic light detection system software module configured to detect the states of known traffic signals, a school bus detection system software module configured to detect school busses, construction zone detection system software module configured to detect construction zones, a detection system software module configured to detect one or more persons (e.g. pedestrians) directing traffic, a traffic accident detection system software module configured to detect a traffic accident, an emergency vehicle detection system configured to detect emergency vehicles, etc. These detection system software modules may be incorporated into the perception system 172 or the computing devices 110. Each of these detection system software modules may input sensor data generated by the perception system 172 and/or one or more sensors (and in some instances, map information for an area around the vehicle) into various models which may output a likelihood of a certain traffic light state, a likelihood of an object being a school bus, an area of a construction zone, a likelihood of an object being a person directing traffic, an area of a traffic accident, a likelihood of an object being an emergency vehicle, etc., respectively.

Detected objects, predicted future behaviors, various likelihoods from detection system software modules, the map information identifying the vehicle's environment, position information from the positioning system 170 identifying the location and orientation of the vehicle, a destination for the vehicle as well as feedback from various other systems of the vehicle may be input into a planning system software module of the planning system 168. The planning system may use this input to generate trajectories for the vehicle to follow for some brief period of time into the future based on a current route of the vehicle generated by a routing module of the routing system 166. A control system software module of the computing devices 110 may be configured to control movement of the vehicle, for instance by controlling braking, acceleration and steering of the vehicle, in order to follow a trajectory.

Computing devices 110 may also include one or more wireless network connections 150 to facilitate communication with other computing devices, such as the client computing devices and server computing devices described in detail below. The wireless network connections may include short range communication protocols such as Bluetooth, Bluetooth low energy (LE), cellular connections, as well as various configurations and protocols including the Internet, World Wide Web, intranets, virtual private networks, wide area networks, local networks, private networks using communication protocols proprietary to one or more companies, Ethernet, WiFi and HTTP, and various combinations of the foregoing.

The computing devices 110 may control the vehicle in an autonomous driving mode by controlling various components. For instance, by way of example, the computing devices 110 may navigate the vehicle to a destination location completely autonomously using data from the detailed map information and planning system 168. The computing devices 110 may use the positioning system 170 to determine the vehicle's location and perception system 172 to detect and respond to objects when needed to reach the location safely. Again, in order to do so, computing device 110 may generate trajectories and cause the vehicle to follow these trajectories, for instance, by causing the vehicle to accelerate (e.g., by supplying fuel or other energy to the engine or power system 174 by acceleration system 162), decelerate (e.g., by decreasing the fuel supplied to the engine or power system 174, changing gears, and/or by applying brakes by deceleration system 160), change direction (e.g., by turning the front or rear wheels of vehicle 100 by steering system 164), and signal such changes (e.g. by using turn signals). Thus, the acceleration system 162 and deceleration system 160 may be a part of a drivetrain that includes various components between an engine of the vehicle and the wheels of the vehicle. Again, by controlling these systems, computing devices 110 may also control the drivetrain of the vehicle in order to maneuver the vehicle autonomously.

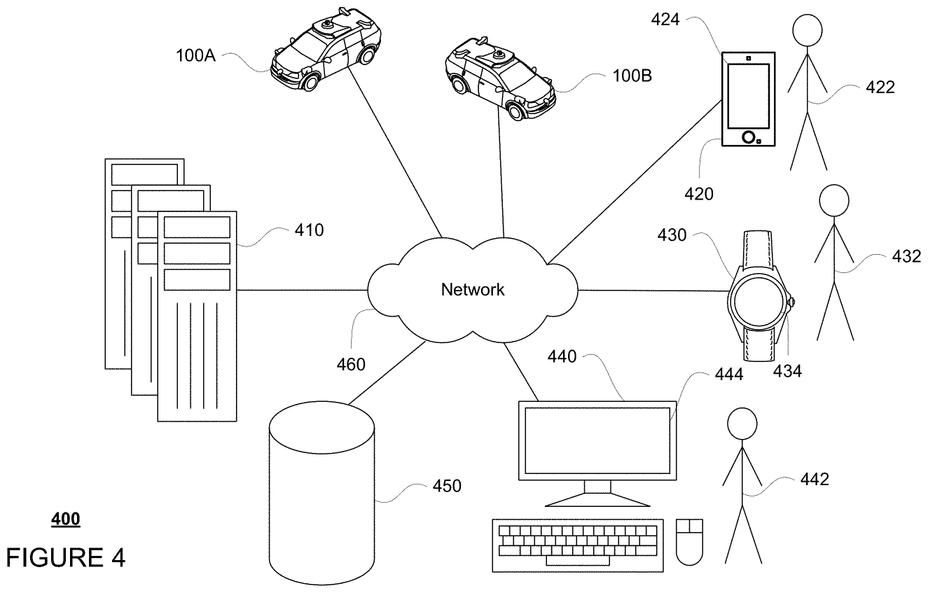

Computing device 110 of vehicle 100 may also receive or transfer information to and from other computing devices, such as those computing devices that are a part of the transportation service as well as other computing devices. FIGS. 3 and 4 are pictorial and functional diagrams, respectively, of an example system 400 that includes a plurality of computing devices 410, 420, 430, 440 and a storage system 450 connected via a network 460. System 400 also includes vehicle 100, and vehicles 100A, 100B which may be configured the same as or similarly to vehicle 100. Although only a few vehicles and computing devices are depicted for simplicity, a typical system may include significantly more.

As shown in FIG. 4, each of computing devices 410, 420, 430, 440 may include one or more processors, memory, instructions and data. Such processors, memories, data and instructions may be configured similarly to one or more processors 120, memory 130, instructions 132 and data 134 of computing device 110.

The network 460, and intervening nodes, may include various configurations and protocols including short range communication protocols such as Bluetooth, Bluetooth LE, the Internet, World Wide Web, intranets, virtual private networks, wide area networks, local networks, private networks using communication protocols proprietary to one or more companies, Ethernet, WiFi and HTTP, and various combinations of the foregoing. Such communication may be facilitated by any device capable of transmitting data to and from other computing devices, such as modems and wireless interfaces.

In one example, one or more computing devices 410 may include one or more server computing devices having a plurality of computing devices, e.g., a load balanced server farm, that exchange information with different nodes of a network for the purpose of receiving, processing and transmitting the data to and from other computing devices. For instance, one or more computing devices 410 may include one or more server computing devices that are capable of communicating with computing device 110 of vehicle 100 or a similar computing device of vehicle 100A as well as computing devices 420, 430, 440 via the network 460. For example, vehicles 100, 100A, may be a part of a fleet of vehicles that can be dispatched by server computing devices to various locations. In this regard, the server computing devices 410 may function as a validation computing system which can be used to validate autonomous control software which vehicles such as vehicle 100 and vehicle 100A may use to operate in an autonomous driving mode. In addition, server computing devices 410 may use network 460 to transmit and present information to a user, such as user 422, 432, 442 on a display, such as displays 424, 434, 444 of computing devices 420, 430, 440. In this regard, computing devices 420, 430, 440 may be considered client computing devices.

As shown in FIG. 4, each client computing device 420, 430, 440 may be a personal computing device intended for use by a user 422, 432, 442, and have all of the components normally used in connection with a personal computing device including a one or more processors (e.g., a central processing unit (CPU)), memory (e.g., RAM and internal hard drives) storing data and instructions, a display such as displays 424, 434, 444 (e.g., a monitor having a screen, a touchscreen, a projector, a television, or other device that is operable to display information), and user input devices 426, 436, 446 (e.g., a mouse, keyboard, touchscreen or microphone). The client computing devices may also include a camera for recording video streams, speakers, a network interface device, and all of the components used for connecting these elements to one another.

Although the client computing devices 420, 430, and 440 may each comprise a full-sized personal computing device, they may alternatively comprise client computing devices capable of wirelessly exchanging data with a server over a network such as the Internet. By way of example only, client computing device 420 may be a mobile phone or a device such as a wireless-enabled PDA, a tablet PC, a wearable computing device or system, or a netbook that is capable of obtaining information via the Internet or other networks. In another example, client computing device 430 may be a wearable computing system, depicted as a smart watch as shown in FIG. 4. As an example the user may input information using a small keyboard, a keypad, microphone, using visual signals with a camera, or a touch screen.

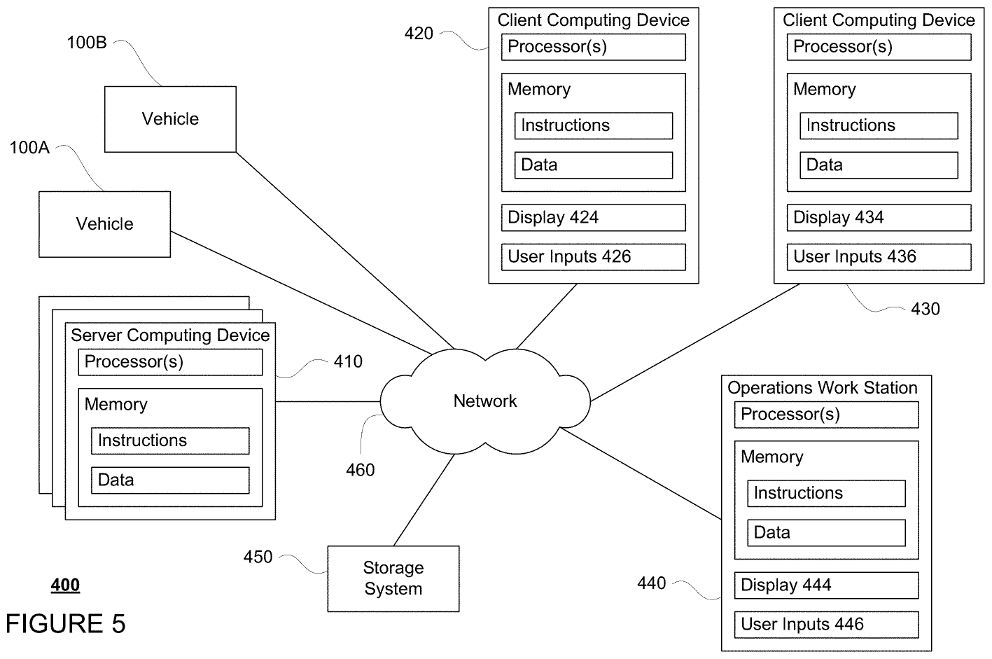

In some examples, client computing device 420 may be a mobile phone used by passenger of a vehicle. In other words, user 422 may represent a passenger. In addition, client computing device 430 may represent a smart watch for a passenger of a vehicle. In other words, user 432 may represent a passenger. The client computing device 430 may represent a workstation for an operations person, for example, a remote assistance operator or someone who may provide remote assistance to a vehicle and/or a passenger. In other words, user 442 may represent a remote assistance operator. Although only a few passengers and operations person are shown in FIGS. 4 and 5, any number of such, passengers and remote assistance operators (as well as their respective client computing devices) may be included in a typical system.

As with memory 130, storage system 450 can be of any type of computerized storage capable of storing information accessible by the server computing devices 410, such as a hard-drive, memory card, ROM, RAM, DVD, CD-ROM, write-capable, and read-only memories. In addition, storage system 450 may include a distributed storage system where data is stored on a plurality of different storage devices which may be physically located at the same or different geographic locations. Storage system 450 may be connected to the computing devices via the network 460 as shown in FIGS. 4 and 5, and/or may be directly connected to or incorporated into any of the computing devices 110, 410, 420, 430, 440, etc.

Storage system 450 may store various types of information as described in more detail below. This information may be retrieved or otherwise accessed by a server computing device, such as one or more server computing devices 410, in order to perform some or all of the features described herein. For instance, storage system 450 may store logged data. This logged data may include, for instance, sensor data generated by a perception system, such as perception system 172 of vehicle 100. As an example, the sensor data may include raw sensor data as well as data identifying defining characteristics of perceived objects such as shape, location, orientation, speed, etc. of objects such as vehicles, pedestrians, bicyclists, vegetation, curbs, lane lines, sidewalks, crosswalks, buildings, etc. The logged data may also include “event” data identifying different types of events such as collisions or near collisions with other objects, planned trajectories describing a planned geometry and/or speed for a potential path of the vehicle 100, 100A, actual locations of the vehicles at different times, actual orientations/headings of the vehicle at different times, actual speeds, accelerations and decelerations of the vehicle at different times, classifications of and responses to perceived objects, behavior predictions of perceived objects, status of various systems (such as acceleration, deceleration, perception, steering, signaling, routing, power, etc.) of the vehicle at different times including logged errors, inputs to and outputs of the various systems of the vehicle at different times, etc. As such, these events and the sensor data may be used to “recreate” the vehicle's environment, including perceived objects, and behavior of a vehicle in a simulation. In some instances, the logged data may be annotated with information identifying behaviors of the autonomous vehicle, such as passing, changing lanes, merging, etc., as well as with information identifying behaviors of other agents in the logged data, such as passing or overtaking the autonomous vehicle, changing lanes, merging, etc.

The storage system may also store interactive agents, or data and instructions that can be used to generate a simulated road user in order to interact with a virtual vehicle in a simulation. Because there are different types of road users, there may be different types of interactive agents. For instance, there may be interactive agents for vehicles (or to specific types of vehicles, such as an autonomous vehicle, bus, van, small car, truck, motorcycle, emergency vehicles (e.g. police car, ambulance, etc.), and other larger vehicles as well as non-vehicles such as pedestrians, crowds of pedestrian, pedestrians with strollers, children, scooters, wild animals and pets, etc.

Because humans are generally unpredictable, the interactive agents may be generated by establishing a set of characteristics. Typically, these characteristics may relate to the reaction times, for instance for reacting to visual or audible stimuli by moving a foot or a hand to change braking, acceleration, and/or steering behaviors of a vehicle as with a human driver, pedestrian, bicyclist. In other words, the interactive agents may include models for how an ideal, average, or below average human would brake or swerve which are available from existing human reaction research. In this regard, the models may be approximate and hand tuned, and likely to respond in more predictable ways than typical human drivers. In some instances, the models may also have behavioral rules, such as how a typical driver would behave at a 4-way stop or respond to a child in the environment, etc. However, such modeling may essentially ignore the intent and personal of the original agent from the logged data.

In addition, the storage system 450 may also store autonomous control software which is to be used by vehicles, such as vehicle 100, to operate a vehicle in an autonomous driving mode. This autonomous control software stored in the storage system 450 may be a version which has not yet been tested or validated. Once validated, the autonomous control software may be sent, for instance, to memory 130 of vehicle 100 in order to be used by computing devices 110 to control vehicle 100 in an autonomous driving mode.

### Example Methods

In addition to the operations described above and illustrated in the figures, various operations will now be described. It should be understood that the following operations do not have to be performed in the precise order described below. Rather, various steps can be handled in a different order or simultaneously, and steps may also be added or omitted.

As noted above, when running log-based simulations, if the behavior of the simulated vehicle is different from the vehicle that captured the log data segment, the simulated vehicle and the vehicle that captured the log data may have different fields of view or perspectives. Because of unavoidable limits on the sensor data included in the logs due to the limits of these devices and other factors like occlusions, the log data will not include the absolute “ground truth” of the world or rather, all sensor data from all possible perspectives for the log data segment. As a result, problems may occur when objects that were previously occluded with respect to the vehicle that captured the log data segment are now interacting with the simulated vehicle. Such objects may appear “from nowhere” and may “pop up” and surprise the simulated vehicle.

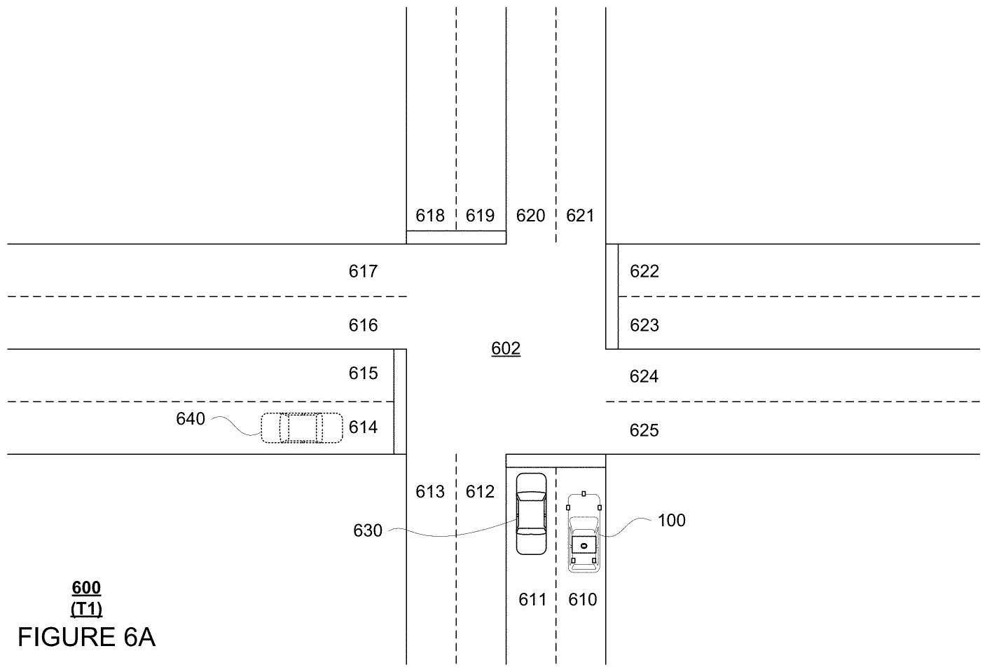

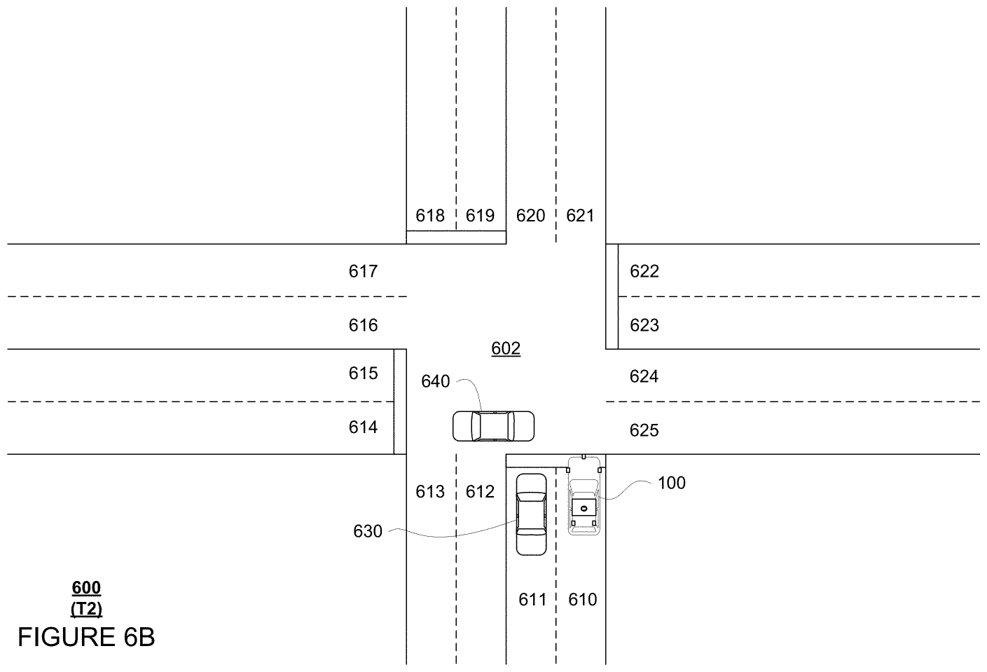

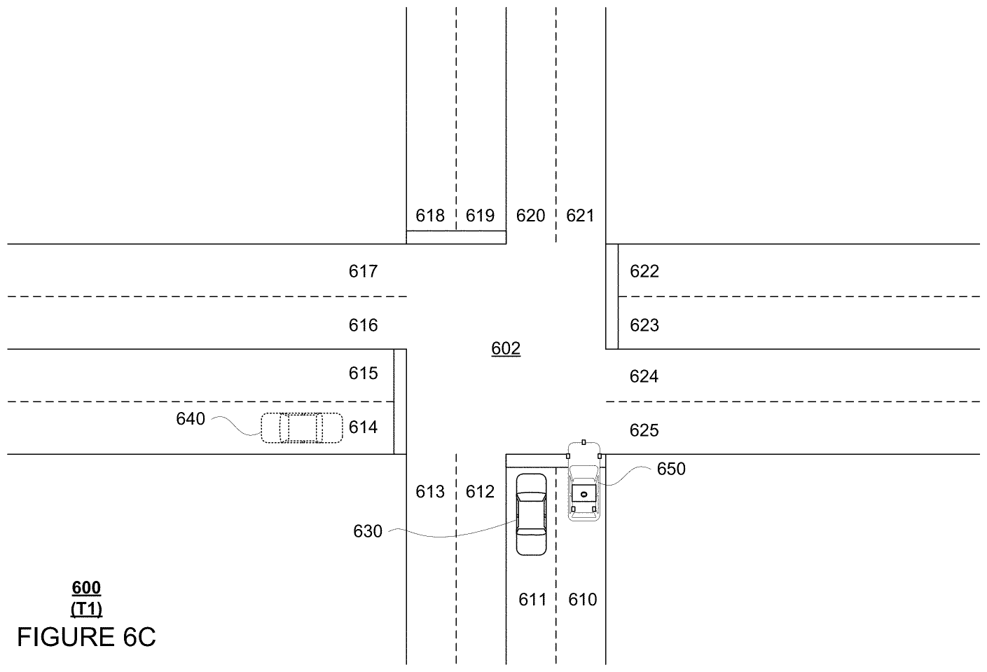

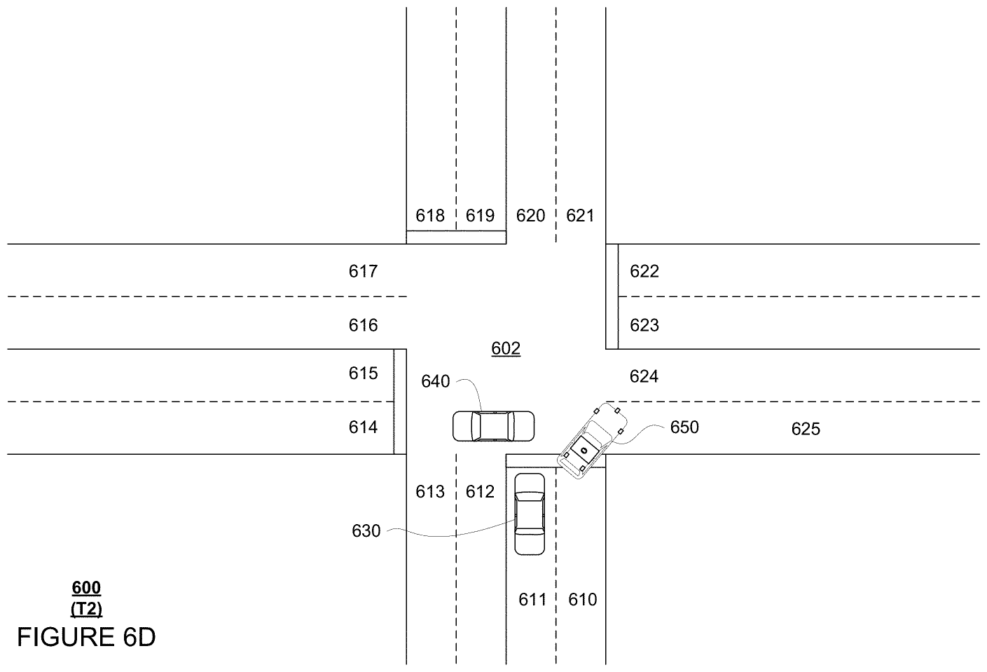

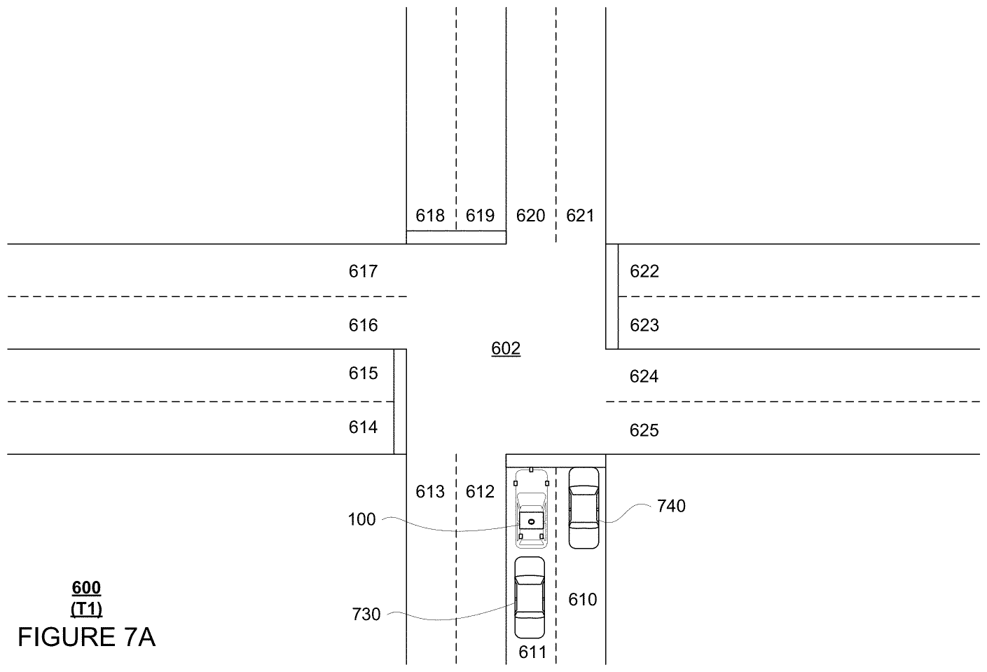

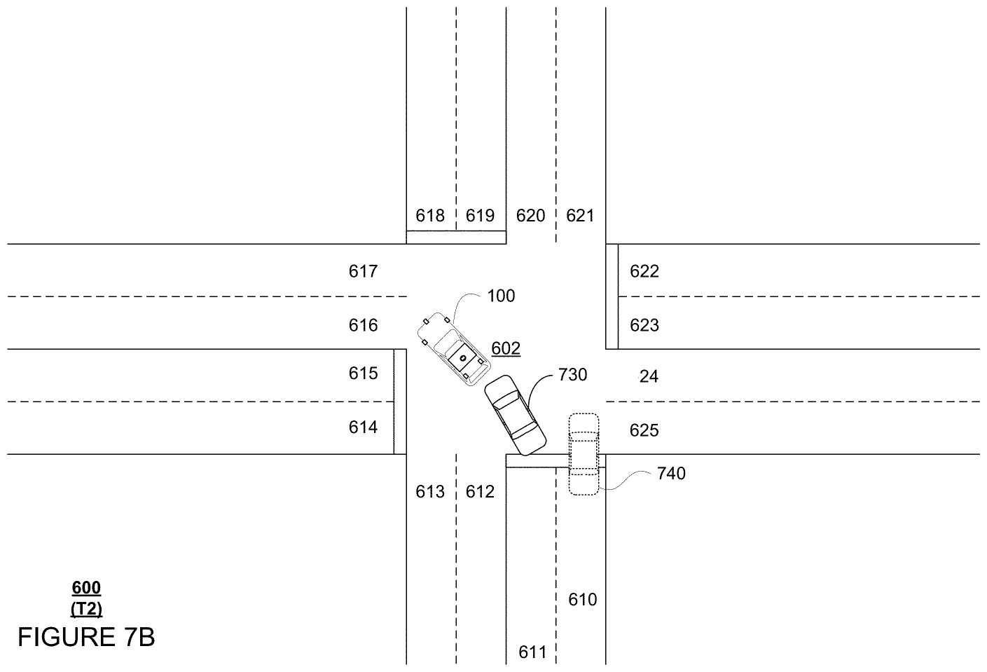

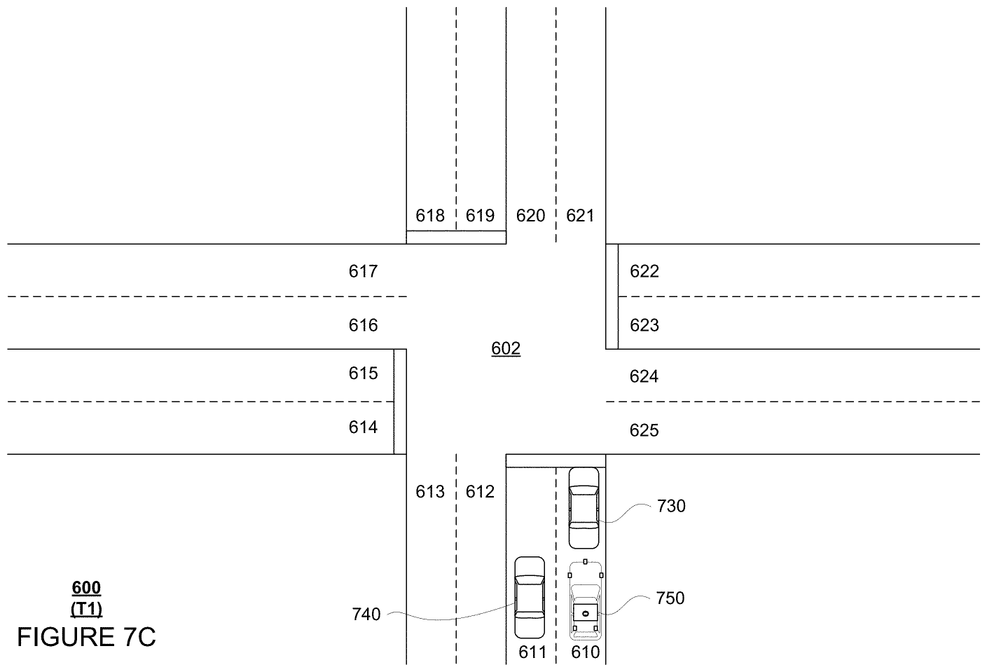

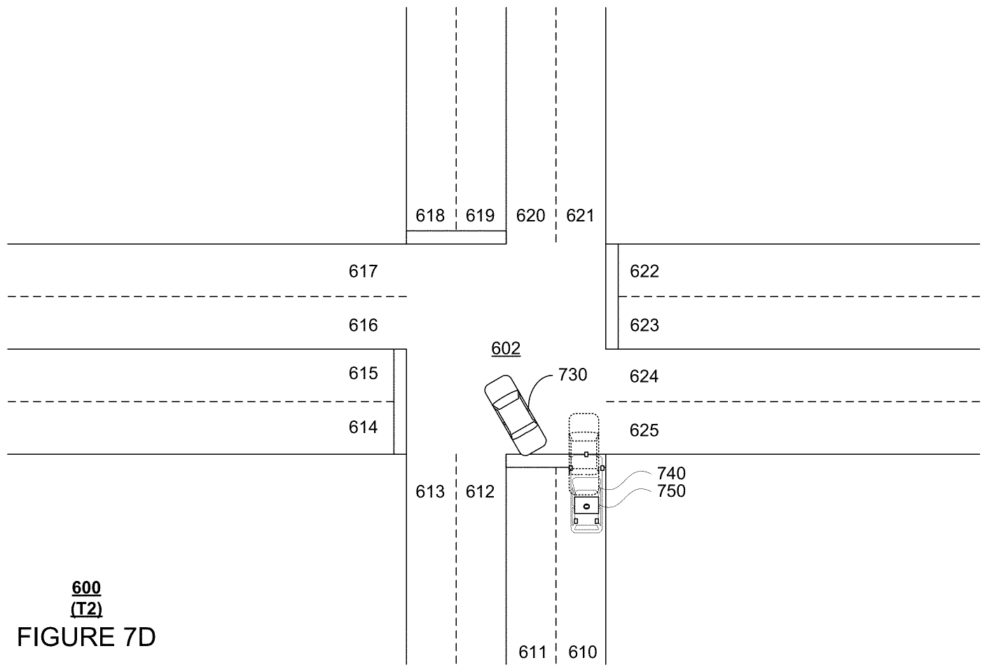

FIGS. 6A-6D and 7A-7D provide two different examples of this. FIGS. 6A-6B represent two different points in time, T1 and T2, for a first log data segment captured at a geographic area 600. The point in time, T1, of FIG. 6A, is earlier than the point in time, T2, of FIG. 6B. In addition, the area 600 corresponds to the area of map information 200. In this regard, intersection 602 corresponds to the shape and location of intersection 202 and lanes 610-625 correspond to the shape and location of lanes 210-225. In addition, each of vehicles 630, 640 represent road user objects for the first log data segment.

Turning to FIG. 6A, at T1 in the first log data segment, vehicle 100 was located in lane 610 and approaching intersection 602. Vehicle 630 is located to the left of the vehicle 100 in lane 612 and is also approaching (or stopped) intersection 602. In this example, the position of vehicle 630 may prevent the perception system from seeing an object such as vehicle 640, located in lane 614, represented by dashed-line to indicate that vehicle 640 is not included in the first log data segment at T1. Turning to FIG. 6B, at T2 in the first log data segment, vehicle 100 was closer to intersection 602. Vehicle 630 is located to the left of the vehicle 100 in lane 612 and is also stopped at intersection 602. In this example, the position of vehicle 630 may allow the perception system 172 to perceive the vehicle 640 (no longer shown in dashed line) at T2 in the first log data segment, but not at T1 in the first log data segment, as shown in FIG. 6A.

FIGS. 6C-6D represents the points time, T1 and T2, for a first simulation run using the log data segment of FIGS. 6A-6B. Turning to FIG. 6C, at T1 a simulated vehicle 650 is located partially in lane 610 and partially in intersection 602. In this example, the location of the simulated vehicle 650 is no longer the same as the location of the vehicle 100 at T1 in the first simulation. The vehicle 630 is located to the left of the vehicle 100 in lane 612 and is also approaching (or stopped) intersection 602. As can be seen, the simulation does not include a representation of the vehicle 640 (again shown in dashed-line to indicate that the vehicle 640 is not included in the simulation at T1). Turning to FIG. 6D, at T2 in the first simulation, the simulated vehicle 650 has pulled further into the intersection 602, immediately in front of vehicle 640 which appears from nowhere or pops up unexpectedly. In other words, because the first log data at T1 (shown in FIG. 6A) did not include the location of vehicle 640, the simulated vehicle 650 may inappropriately pull forward because at T1 in the first simulation, there is no approaching vehicle in lane 614. This may result in a potential collision with the vehicle 640 in the first simulation, even though the simulated vehicle would not have otherwise pulled further into the intersection 602.

Turning to the example of FIGS. 7A-7D, FIGS. 7A-7B represent two different points in time, T1 and T2, for a second log data segment captured at the geographic area 600. The point in time, T1 in the second log data segment, of FIG. 7A, is earlier than the point in time, T2 in the second log data segment, of FIG. 7B. In addition, the area 600 corresponds to the area of map information 200. In this regard, intersection 602 corresponds to the shape and location of intersection 202 and lanes 610-625 correspond to the shape and location of lanes 210-225. In addition, each of vehicles 730, 740 represent road user objects for the second log data segment.

Turning to FIG. 7A, at T1 in the second log data segment, vehicle 100 was located in lane 612 and approaching intersection 602. Vehicle 730 is located immediately in front of the vehicle 100 in lane 612 and is also approaching (or stopped) intersection 602. In this example, the position of vehicle 630 may allow the perception system 172 to perceive the vehicle 740 at T1. In this regard, vehicle 740 may be in lane 610 and moving into the intersection 602. Turning to FIG. 7B, at T2 in the second log data segment, vehicle 100 makes a left at the intersection 602 and moves towards lane 616. Vehicle 730 follows immediately behind vehicle 100 and moves into intersection 602. In this example, the position of vehicle 730 at T2 in the second log data segment may prevent the perception system from seeing an object, located in lane 610, represented in dashed-line to indicate that vehicle 740 is not included in the second log data segment at T2.

FIGS. 7C-7D represents the points time, T1 and T2, for a second simulation run using the second log data segment of FIGS. 7A-7B. Turning to FIG. 7C, at T1 in the second simulation, a simulated vehicle 750 is located partially in lane 610 and partially in intersection 602. In this example, the location of the simulated vehicle 750 is no longer the same as the location of the vehicle 100 at T1 in the second simulation. The vehicle 730 is located to the left of the vehicle 100 in lane 612 and is also approaching (or stopped) intersection 602. As can be seen, the simulation does not include a representation of the vehicle 740 (again shown in dashed-line to indicate that the vehicle 740 is not included in the second simulation at T2). Turning to FIG. 7D, at T2 in the second simulation, the simulated vehicle 650 has pulled further towards the intersection 602, and is now intersecting with or “colliding” with vehicle 740 which appears from nowhere or pops up unexpectedly. In other words, because the log data at T2 (shown in FIG. 7B) did not include the location of vehicle 740, the simulated vehicle 750 may inappropriately pull forward, because at T1 in the second simulation, there is no vehicle 740 immediately in front of the simulated vehicle 750. If there were a vehicle 740, this would have resulted in a potential collision with the vehicle 740 in the simulation, even though the simulated vehicle would not have otherwise pulled further into the intersection 602 if there were a vehicle 740.

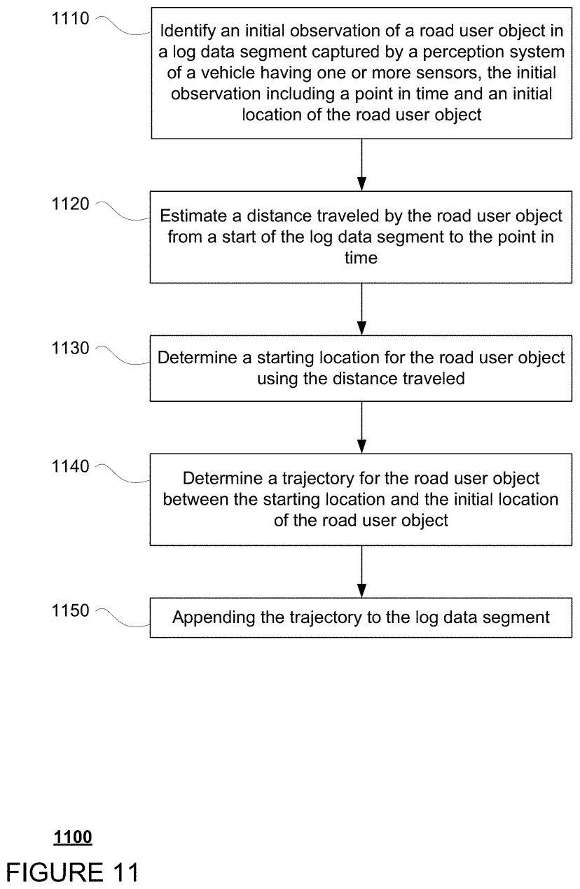

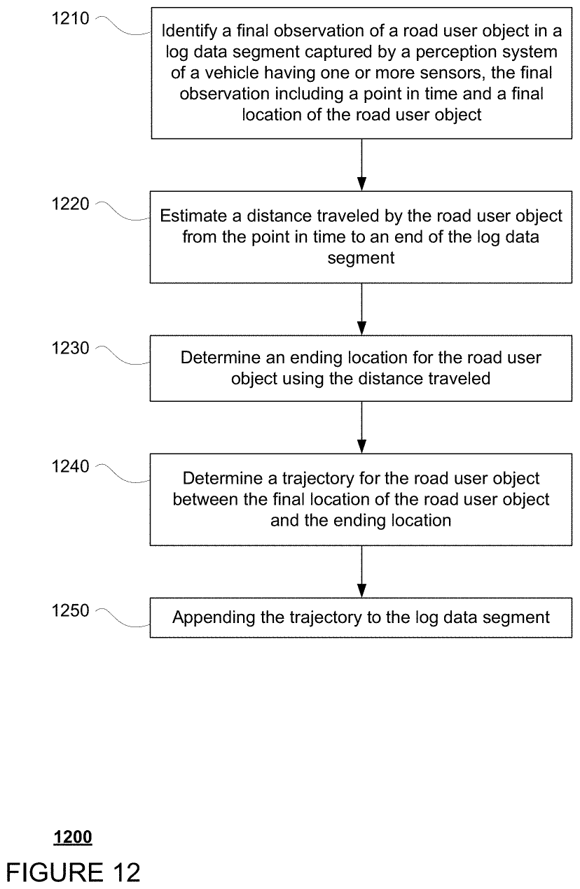

To address these issues, the log data may be analyzed in order to backward or forward interpolate the trajectories of objects. FIGS. 11 and 12 includes an example flow diagrams 1100, 1200 of some of the examples for improving realism in simulations for testing software for operating a vehicle in an autonomous driving mode, which may be performed by one or more processors such as processors 120 of computing devices 110 in order to detect and identify anomalies with traffic lights as well as to control a vehicle in an autonomous driving mode accordingly. FIG. 11 relates to backwards interpolation, while FIG. 12 relates to forward interpolation.

Turning to block 1110 of FIG. 11, an initial observation of a road user object in a log data segment captured by a perception system of a vehicle. The perception system having one or more sensors is identified. As noted above, the vehicle may be operating in an autonomous driving mode and the log data segment may include other data generated by various systems of the vehicle. The initial observation includes a point in time and an initial location of the road user object. For the backward interpolation, the log data segment may first be analyzed to identify objects, including road users such as pedestrians, bicyclists and other vehicles. The analysis may also include identifying a point in time when each road user object is first observed in the log data segment. Other pre-processing steps, such as identifying and merging objects which appear to be the same object (e.g. a person walks behind another object and then later appears).

At block 1120 of FIG. 11, a distance traveled by the road user object from a start of the log data segment to the point in time is estimated. To estimate a distance traveled by the road user object, the amount of time or difference between the beginning of the log data segment and the point at which the object is first observed may be determined. For any road user objects which were first observed at a point in time after the beginning of the log data segment, the initial speed of those road user objects may be identified, or rather, the estimated speed of the road user object at the point in time when the road user object is first observed. As noted above, this initial speed may be included in the log data segment. This initial speed may be multiplied by the amount of time between the beginning of the log data segment and the point at which the object is first observed to estimate the distance traveled by the object.

At block 1130 of FIG. 11, a starting location for the road user object using the distance traveled is identified. To do so, a lane for the road user object when the road user object is first observed may be determined. The lane may be determined based on both the location of the road user as well as the heading of the road user at the point in time when the road user was first observed. Again, this information may be included in the log data segment. By comparing the location to pre-stored map information identifying the shape and locations of lanes, the closest lane that is consistent with or has the same or similar heading as the road user object may be identified. The lane may then be traversed backwards (opposite of the direction of the heading of the object or the lane) the estimated distance traveled to determine a starting location for the road user object at the beginning of the log segment (or future simulation) along the center of the lane.

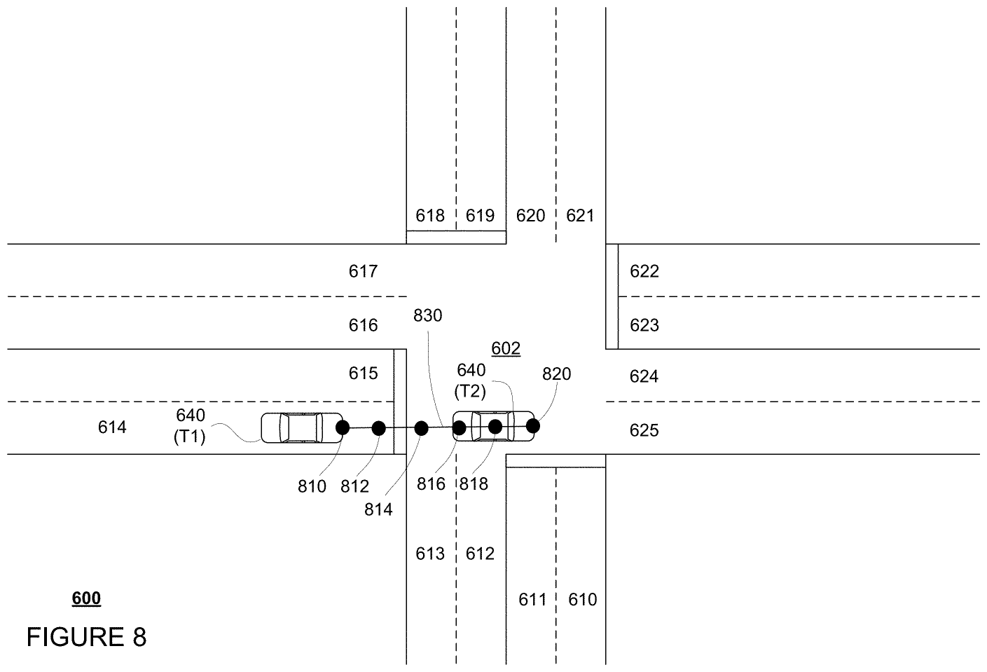

Returning to the example of the first log data segment of FIGS. 6A-6B, as shown in FIG. 8, the initial observation 820 of vehicle 640 occurs at T2. At this time, the vehicle 640 is located in the intersection 602 heading away from lane 614 and towards lane 625. In this regard, vehicle 640 is closest to these lanes and likely coming from lane 614 given the heading of the vehicle 640 at T2. Traversing backwards along lane 614, at T1, given a current velocity of the vehicle 640 at T2, at T1, vehicle 640 may have a starting location 810.

At block 1140 of FIG. 11, a trajectory for the road user object between the starting location and the initial location of the road user object is determined. From the starting location to the initial location, a plurality of waypoints (intermediate states for the road user object) and corresponding timestamps for the object may be determined. Each waypoint may be approximately 0.1 second apart or at a rate of 11 Hz which may be determined based on a frame rate of the log data. This frame rate may be dictated by a frame rate of the sensors that captured the sensor data of the log data segment. A trajectory may then be determined for the road user object. The trajectory may include each of the waypoints as well as a timestamp for the road user object.

Returning to FIG. 8, a plurality of waypoints 812, 814, 816, 818 between the initial observation 820 and the starting location 810 may be determined or interpolated for example, by traversing backwards along the center of lane 614. Together, the starting location, plurality of waypoints 812, 814, 816, 818, and the initial observation may form a trajectory 830 for the vehicle 640. Each of the plurality of waypoints represents an intermediate state for the vehicle 640. Again, the timing of these waypoints may be based on the frame rate of the first log data segment.

At block 1150 of FIG. 11, the trajectory is appended to the log data segment. This trajectory (including road user objects, waypoints—including starting or ending location—and timestamps) may be appended to the log data segment and used to run simulations. These simulations may be used to evaluate the performance of the autonomous vehicle software used to control the simulated vehicle in the simulation, for instance by identifying collisions, near collisions, uncomfortable levels of braking, swerving, and other events. Simulations may also be used to test other aspects of the vehicle's systems, such as recall on the ability to identify specific types of road users. In this regard, the trajectory 830 may be appended to the first log segment data.

A similar approach may be used to interpolate forward. Turning to block 1210 of FIG. 12, a final observation of a road user object in a log data segment captured by a perception system of a vehicle. The perception system having one or more sensors. As noted above, the vehicle may be operating in an autonomous driving mode and the log data segment may include other data generated by various systems of the vehicle. The final observation includes a point in time and a final location of the road user object. As with the backwards interpolation, for the forward interpolation, the log data segment may first be analyzed to identify objects, including road users such as pedestrians, bicyclists and other vehicles. The analysis may also include identifying a point in time when each road user object is last observed in the log data segment. Again, other pre-processing steps, such as identifying and merging objects which appear to be the same object (e.g. a person walks behind another object and then later appears).

At block 1220 of FIG. 12, a distance traveled by the road user object from the point in time to an end of the log data segment is estimated. To estimate a distance traveled by the road user object, the amount of time or the difference between the point at which the object is last observed and the end of the log data segment may be determined. For any road user objects which were last observed before the end of the log data segment, the final speed of those road user objects may be identified, or rather, the estimated speed of the road user object at the point in time when the road user object is last observed. As noted above, this final speed may be included in the log data segment. This final speed may be multiplied by the amount of time between the point at which the object is last observed and the end of the log data segment to estimate the distance traveled by the object.

In situations in which a road user object is observed as being stationary, the server computing devices 410 may assume that the road user object will remain stationary. In some instances, additional heuristics may be used to predict whether the road user object will move in the future, such as whether the object is stopped at a stop sign or traffic light, etc.

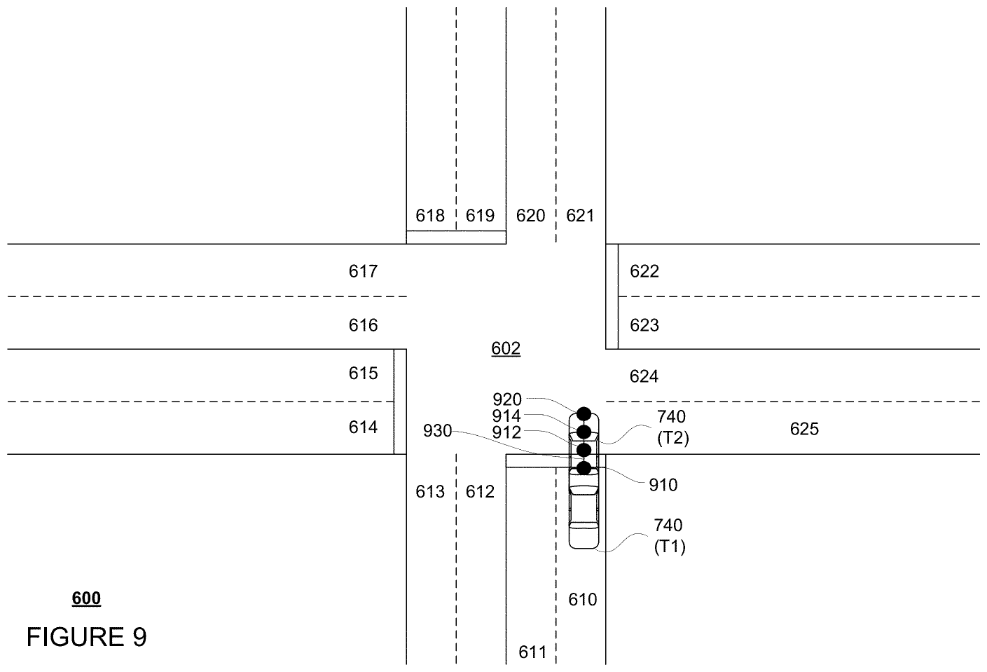

Returning to the example of the second log data segment of FIGS. 7A-7B, as shown in FIG. 9, the final observation 910 of vehicle 740 occurs at T1. At this time, the vehicle 740 is located in lane 610 and about to enter intersection 602 heading towards lane 625. In this regard, vehicle 740 is closest to these lanes and likely coming from lane 614. Traversing forward along lane 614, at T2, given a final speed of the vehicle 740 at T1, at T2, vehicle 740 may have a final location 920.

At block 1230 of FIG. 12, an ending location for the road user object using the distance traveled is identified. To do so, a lane for the road user object when the road user object is last observed may be determined. The lane may be determined based on both the location of the road user as well as the heading of the road user at the point in time when the road user was first observed. Again, this information may be included in the log data segment. By comparing the location to pre-stored map information identifying the shape and locations of lanes, the closest lane that is consistent with or has the same or similar heading as the road user object may be identified. The lane may then be traversed forward (in the direction of the heading of the object or the lane) the estimated distance traveled to determine an ending location for the road user object at the beginning of the log segment (or future simulation) along the center of the lane.

At block 1240 of FIG. 12, a trajectory for the road user object between the ending location and the final location of the road user object is determined. From the final observation to the ending location, a plurality of waypoints (intermediate states for the road user object) and corresponding timestamps for the object may be determined. Each waypoint may be approximately 0.1 second apart or at a rate of 11 Hz which may be determined based on a frame rate of the log data. This frame rate may be dictated by a frame rate of the sensors that captured the sensor data of the log data segment. A trajectory may then be determined for the road user object. The trajectory may include each of the waypoints as well as a timestamp for the road user object.

Returning to FIG. 9, a plurality of waypoints 912, 914 between the final observation 910 and the ending location 920 may be determined or interpolated for example, by traversing forward along the center of lane 610. Together, the final observation, plurality of waypoints 912, 914 and the ending location may form a trajectory 930 for the vehicle 740. Each of the plurality of waypoints represents an intermediate state for the vehicle 740. Again, the timing of these waypoints may be based on the frame rate of the first log data segment.

At block 1250 of FIG. 12, the trajectory is appended to the log data segment. Again, this trajectory (including road user objects, waypoints—including starting or ending location—and timestamps) may be appended to the log data segment and used to run simulations. These simulations may be used to evaluate the performance of the autonomous vehicle software used to control the simulated vehicle in the simulation, for instance by identifying collisions, near collisions, uncomfortable levels of braking, swerving, and other events. Simulations may also be used to test other aspects of the vehicle's systems, such as recall on the ability to identify specific types of road users. In this regard, the trajectory 930 may be appended to the first log segment data.

In some instances, simulations may be run which involve replacing the road user object with a model agent which can react to the actions of the simulated vehicle as well as other objects in the log data segment. Because the appended information will include the location of a road user object before it was actually observed by the vehicle that captured the log data, the road user object can actually be replaced by a model agent at a point in time prior to the road user object being observed in the log data segment.

Although the examples described above relate to road user objects identified in the log data, the features described herein may be useful for other agents that are to be added to a simulation. For instance, when agents are added to the simulation at a certain point in time in order to interact with the simulated vehicle, a similar process may be used to determine where the agent should start at the beginning of the simulation or at least, at some time earlier than the interaction. In this way, agents may be placed in the simulation at locations where they will eventually interact with the simulated vehicle in the desired way.

Although the examples herein relate to relatively short simulations, e.g. on the order of 1 minute or more or less, such features may be especially useful for much longer simulations (˜30 minutes or above) which can have a relatively large number of road user objects and/or agents appearing at different points in time.

In order to ensure that the appended data is still realistic, additional constraints may be considered. For example, ideally, there should not be any time or space overlap with the vehicle that captured the log data. Similarly, there should not be any time or space overlap with any other of the road user objects in the log data segment. As such, if any overlap with the vehicle that captured the log data occurs, then the analysis would stop, and no information would be appended to the log data segment. However, if there is any overlap with another road user object, depending on the use case, the analysis may be stopped or may continue either allowing the overlap or only allowing some predetermined amount of overlap.

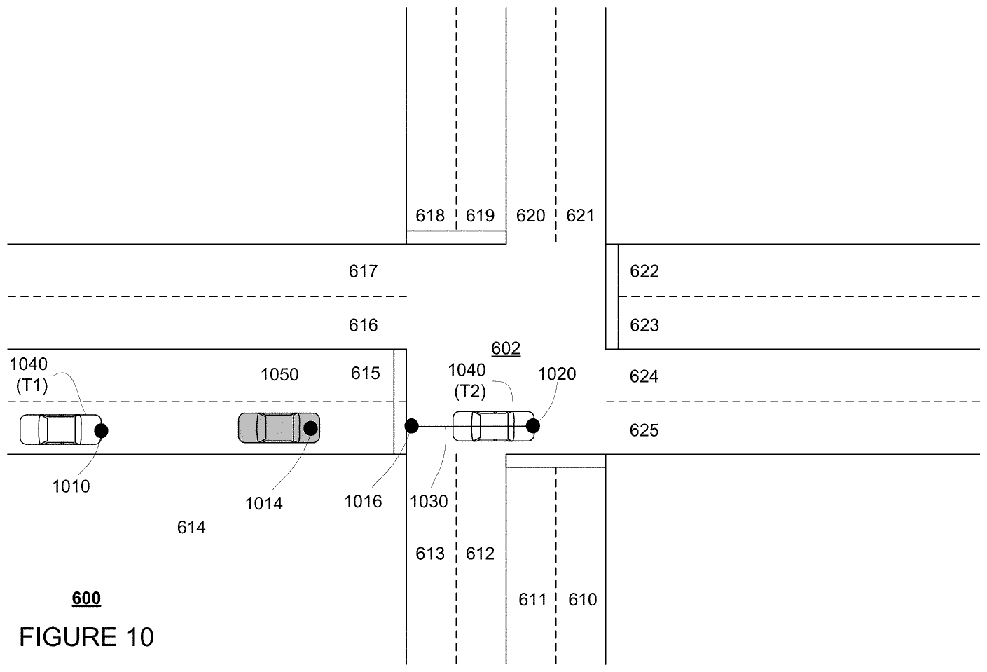

For example, turning to the example of FIG. 10, when interpolating a plurality of waypoints, including waypoints 1014, 1016, between a starting location 1010 and an initial observation 1020 for a vehicle 1040, at waypoint 1014, the location of vehicle 1040 intersects with another vehicle 1050 in the log data segment. As such, the interpolation may stop at waypoint 1016. The trajectory 1030 between waypoint 1016 and the initial observation 1020 may be appended to the log data segment and used for future simulations.

In some instances, there may be different requirements for different types of simulations or those with different purposes. For example, continuing with the example of FIG. 10, when the purpose of the simulation is to test recall with regard to the types of road users detected by the perception system, the road user object for the vehicle 1040 may start at the location of waypoint 1016 and follow trajectory 1030. As another example, when the purpose of the simulation is to test whether the simulated vehicle will be in a collision, the road user object for vehicle 1040 may start at the location of the initial observation 1020 (i.e. ignore the appended trajectory 1030).

As another way to improve realism, the starting or ending location and/or speed of the road user object may be varied. For instance, a vehicle approaching an intersection may tend to slow down, thus, the speed of the vehicle may assume to have decreased as it approaches an intersection and/or increase as the vehicle moves away from an intersection. As one example, the road user object could be replaced with an intelligent agent having the same initial state and simulate forward in time for a brief period. This would allow the intelligent agent to identify what it would do in the same situation and use those behaviors or trajectory. As another example, certain metrics could be defined for candidate behaviors, and the behavior with the highest score could be selected for the simulation. Example metrics may include hard brake times, distance to road center, acceleration, etc. Again, this may result in different possible waypoints and really, candidate trajectories which could be appended to create different simulations with the same log data segment. As yet another way to improve realism, when a road user object appears to be away from the center of the identified lane, rather than immediately snapping that road user object to the center of the lane, the road user object may be snapped at the starting location or ending location. This may allow for a more realistic progression of road user objects in simulations.

As another way to improve realism, when interpolating, rather than using only an initial observation location and a starting and ending location, an intermediate location of the object may be used. The interpolation can then proceed between the intermediate location and the initial observation location as well as between the intermediate location and the starting or ending location. For instance, pre-stored trajectories for autonomous vehicles as well as any other road users observed on the road may be used to determine an intermediate point. For instance, using a road user object's first observed location and another observed location at some other point in time (can be fixed or arbitrary, say 5 seconds after it first appeared). These two locations can be used to query the pre-stored trajectories. A database of the pre-stored trajectories may be constraint based, so if several position constraints are provided, the database may return trajectories that satisfy these constraints (e.g. travel to point A then point B). Such trajectories may be used to select an intermediate point.

The interpolation described herein may be performed only for certain types of road user objects having certain characteristics. For example, the interpolation would not be useful for pedestrians as they do not typically walk in the center of a lane. At the same time, the interpolation may be especially useful for objects like motorcycles and vehicles which typically drive in the middle of a lane or bicyclists traveling in bicycle lanes. As another example, if the speed of an object is very low, e.g. less than 1 or 2 miles per hour, the road user object may actually be a parked vehicle. In such cases, rather than estimating a starting location or an ending location, such parked vehicles may simply be “fixed” to these locations. In other instances, road users may appear from driveways. In such cases, if the first observation of a road user object in the log segment is too far from any lane center, such as 11 meters or more or less, it may suggest that the road user object is currently not on any lane, but is close to a driveway, the starting location may be identified as the driveway.

The features described herein may provide for a safe, effective, and realistic way of testing software for autonomous vehicles while at the same time improving the realism of such simulations. For example, by appending the information to log data segments, this may enable simulations to be run without the concern of objects appearing “from nowhere” or “popping up” and surprising the simulated vehicle in an unrealistic way. In addition, as noted above, the point at which such road user objects may be replaced by model agents is earlier than if such information were not appended to the log data segments. Moreover, in situations where a new agent is added (not necessarily replacing a road user object) to a simulation, the features described herein may identify exactly where the new agent should appear at the start of the simulation. Both of these features may allow for the running of more realistic simulations that are significantly longer than 1 minute or more or less. Finally, as the perception system may take some time (e.g. a warm up period) before the system can confidently detect an object and its characteristics, by injecting a road user object or agent earlier into a simulation, this can save the “warm up” time and improve sensor recall in the simulation.

Unless otherwise stated, the foregoing alternative examples are not mutually exclusive, but may be implemented in various combinations to achieve unique advantages. As these and other variations and combinations of the features discussed above can be utilized without departing from the subject matter defined by the claims, the foregoing description of the embodiments should be taken by way of illustration rather than by way of limitation of the subject matter defined by the claims. In addition, the provision of the examples described herein, as well as clauses phrased as “such as,” “including” and the like, should not be interpreted as limiting the subject matter of the claims to the specific examples; rather, the examples are intended to illustrate only one of many possible embodiments. Further, the same reference numbers in different drawings can identify the same or similar elements.

1. A method for improving realism in simulations for testing software for operating a vehicle in an autonomous driving mode, the method comprising:
identifying, by one or more processors, an initial observation of a road user object in a log data segment captured by a perception system of a vehicle, the perception system having one or more sensors, the initial observation including a point in time and an initial location of the road user object;
estimating, by the one or more processors, a distance traveled by the road user object from a start of the log data segment to the point in time;
determining, by the one or more processors, a starting location for the road user object using the distance traveled;
determining, by the one or more processors, a trajectory for the road user object between the starting location and the initial location of the road user object; and
appending, by the one or more processors, the trajectory to the log data segment.

2. The method of claim 1, wherein the initial observation includes a speed of the road user object at the point in time, and wherein estimating the distance traveled by the road user object is based on the speed.

3. The method of claim 1, wherein estimating the distance traveled is further based on a difference between the point in time and the start of the log data segment.

4. The method of claim 3, wherein determining the starting location includes:
identifying a lane for the road user object; and
traversing the lane backwards from the initial location using the distance traveled to determine the starting location.

5. The method of claim 4, wherein the initial observation includes a heading for the road user object and wherein identifying the lane for the road user object is based on the heading for the road user object and a heading of the lane.

6. The method of claim 4, wherein the initial observation includes a heading for the road user object and wherein identifying the lane for the road user object includes using pre-stored map information to identify a closest lane to the initial location of the road user object having a heading that is consistent with the heading for the road user object.

7. The method of claim 4, wherein the starting location is at a center of the lane.

8. The method of claim 1, wherein determining the trajectory includes determining a plurality of waypoints between the starting location and the initial location of the road user object and a corresponding plurality of timestamps between a beginning of the log data segment and the point in time.

9. The method of claim 8, wherein determining the plurality of waypoints and the corresponding plurality of timestamps is based on a frame rate of the log data segment.

10. The method of claim 1, further comprising, using the log data segment and the appended trajectory to run a simulation.

11. A method for improving realism in simulations for testing software for operating a vehicle in an autonomous driving mode, the method comprising:
identifying, by one or more processors, a final observation of a road user object in a log data segment captured by a perception system of a vehicle, the perception system having one or more sensors, the final observation including a point in time and a final location of the road user object;
estimating, by the one or more processors, a distance traveled by the road user object from the point in time to an end of the log data segment;
determining, by the one or more processors, an ending location for the road user object using the distance traveled;
determining, by the one or more processors, a trajectory for the road user object between the final location of the road user object and the ending location; and
appending, by the one or more processors, the trajectory to the log data segment.

12. The method of claim 11, wherein the final observation includes a speed of the road user object at the point in time, and wherein estimating the distance traveled by the road user object is based on the speed.

13. The method of claim 11, wherein estimating the distance traveled is further based on a difference between the point in time and the end of the log data segment.

14. The method of claim 11, wherein determining the ending location includes:
identifying a lane for the road user object; and
traversing the lane forward from the final location using the distance traveled to determine the ending location.

15. The method of claim 14, wherein the final observation includes a heading for the road user object and wherein identifying the lane for the road user object is based on the heading for the road user object and a heading of the lane.

16. The method of claim 14, wherein the final observation includes a heading for the road user object and wherein identifying the lane for the road user object includes using pre-stored map information to identify a closest lane to the final location of the object having a heading that is consistent with the heading for the road user object.

17. The method of claim 14, wherein the ending location is at a center of the lane.

18. The method of claim 11, wherein determining the trajectory includes determining a plurality of waypoints between the ending location and the final location of the road user object and a corresponding plurality of timestamps between the point in time and an end of the log data segment.

19. The method of claim 18, wherein determining the plurality of waypoints and the corresponding plurality of timestamps is based on a frame rate of the log data segment.

20. The method of claim 11, further comprising, using the log data segment and the appended trajectory to run a simulation.
